(19) United States
(12) Patent Application Publication
(10) Pub. No.: US 2017/0336976 A1
(43) Pub. Date: Nov. 23, 2017

(54) DETERMINING RESTING TIMES FOR MEMORY BLOCKS

(71) Applicant: HEWLETT PACKARD ENTERPRISE DEVELOPMENT LP, Houston, TX (US)

(72) Inventors: Gregg B. Lesartre, Fort Collins, CO (US); Naveen Muralimanohar, Palo Alto, CA (US); Lidia Warnes, Rosevill, CA (US)

(21) Appl. No.: 15/535,378

(22) PCT Filed: Dec. 12, 2014
(86) PCT No.: PCT/US2014/069973

§ 371 Date: Jul. 6, 2017

(51) Int. Cl. G06F 3/06; G11C 13/00

(52) U.S. Cl. CPC G06F 3/064; G11C 13/003; G11C 13/0023; G06F 3/0604; G06F 3/0659; G06F 3/0683

(57) ABSTRACT

Example implementations relate to determining resting times for memory blocks. In example implementations, accessed memory blocks in a cross-point non-volatile memory may be tracked. A respective resting time for each of the accessed memory blocks may be determined. An access command may be prevented from being issued to one of the accessed memory blocks.

### BACKGROUND

Memristor memories may be organized into cross-point arrays to achieve high device densities. When data is read from or written to an array, current may be driven into the array. Current being driven into an array may create local heating.

### BRIEF DESCRIPTION OF THE DRAWINGS

The following detailed description references the drawings, wherein:

FIG. 1 is a block diagram of an example system for determining resting times for memory blocks;

FIG. 2 is a block diagram of an example system for tracking recently accessed memory blocks using a table of indicators;

FIG. 3 is a block diagram of an example device that includes a machine-readable storage medium encoded with instructions to enable enforcement of resting times for accessed memory blocks;

FIG. 4 is a block diagram of an example device that includes a machine-readable storage medium encoded with instructions to identify access types for recently accessed memory blocks;

FIG. 5 is a block diagram of an example device that includes a machine-readable storage medium encoded with instructions to determine a physical layout of a memory module;

FIG. 6 is a flowchart of an example method for tracking recently accessed memory blocks;

FIG. 7 is a flowchart of an example method for determining resting times for memory blocks; and

FIG. 8 is a flowchart of an example method for preventing an access command from being issued to a memory block within a predetermined physical distance of a recently accessed memory block.

### DETAILED DESCRIPTION

Current may be driven into an array of a memristor memory when data is read from or written to the array. Current being driven into an array may create local heating of the array, and possibly of surrounding arrays. Because memristor devices may be highly sensitive in their behavior to variations in their operating temperature, repeated accesses to the same arrays in quick succession may cause performance of such arrays to degrade (e.g., bits may be unexpectedly flipped, or read incorrectly). A malicious access pattern may wear out a given memory location through repeated access.

In light of the above, the present disclosure provides for managing accesses of memory locations to minimize local heating improving reliability of memory devices over time. For example, a malicious access pattern may be prevented from immediately accessing the same array multiple times in succession in attempt to wear out the array. In addition, the present disclosure provides for tracking accesses of arrays within the same bank of a memristor memory.

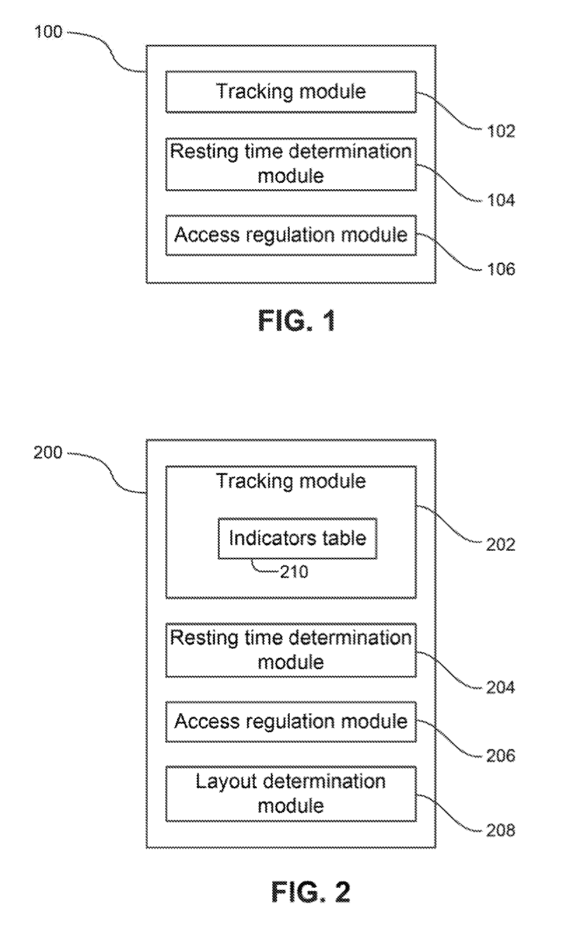

Referring now to the figures. FIG. 1 is a block diagram of an example system 100 for determining resting times for memory blocks. System 100 may be implemented, for example, in a memory controller. In FIG. 1, system 100 includes tracking module 102, resting time determination module 104, and access regulation module 106. As used herein, the terms “include”, “have”, and “comprise” are interchangeable and should be understood to have the same meaning. A module may include a set of instructions encoded on a machine-readable storage medium and executable by a processor. In addition or as an alternative, a module may include a hardware device comprising electronic circuitry for implementing the functionality described below.

Tracking module 102 may track accessed memory blocks in a cross-point non-volatile memory. The cross-point non-volatile memory may be communicatively coupled to system 100. As used herein, the term “memory block” should be understood to refer to a region of a cross-point non-volatile memory that includes a plurality of addresses. For example, a memory block may be a row, column, array, section of an array, group of rows, group of columns, or group of arrays in a cross-point non-volatile memory, or any combination thereof. In some implementations, tracking module 102 may identify (e.g., by analyzing read/write commands) memory blocks in which addresses are being read or written, and store bits corresponding to such addresses (e.g., all or a subset of the address bits, or offset bits that can be translated to a memory location).

The term “access command”, as used, herein with respect to a memory block, should be understood to refer to a command to obtain data from and/or move data into an address in the memory block, or to perform any other manipulation of data in the memory block. For example, an access command may be a command to read an address (or group of addresses) in a memory block, write data to an address (or group of addresses) in the memory block, or perform a combination of operations (e.g., semaphore compare and swap, load and, clear, in-memory compare operations). A memory block from which data has been obtained, into which data has been moved, or in which data has been manipulated in response to an access command may be referred to herein as an “accessed memory block”. A memory block that includes an address from which data is to be obtained, into which data is to be moved, or in which data is to be manipulated in response to an access command may be referred to herein, as the memory block at which the access command is “directed”.

In some implementations, a cross-point non-volatile memory for which tracking module 102 tracks accessed memory blocks may be a memristor memory, and the accessed memory blocks may be arrays of the memristor memory. A memristor memory may have a plurality of banks, and each bank may include a plurality of arrays. In some implementations, a memory block may be a group of arrays in the same bank of the memristor memory. Tracking module 102 may maintain multiple data structures (e.g., registers or tables) for tracking accessed memory blocks in various respective banks, or may track all accessed memory blocks in all banks using the same data structure.

Each bank of a memristor memory may process one access command at, a time. While a bank in a memristor memory is processing an access command (e.g., data is being written to or read from an address in the bank), system 100 may block additional access commands directed at any array in the bank, or reschedule/delay such additional access commands until, a time when the bank is not processing an access command. Banks may process respective access commands in parallel: for example, system 100 may issue a first access command to a first bank in a memristor memory while a second access command is being processed in a second bank in the memristor memory. However, a third access command directed at the first or second bank may be blocked/delayed/rescheduled until processing of the first or second command, respectively, has been, completed.

Resting time determination module 104 may determine a respective resting time for each of the accessed memory blocks. The term “resting time”, as used herein with respect to a memory block, should be understood to refer to a length of time during which the memory block should not be accessed after execution of an access command on the memory block. Enforcing resting times may allow memory blocks to cool after current is driven into them to read or write addresses, and thus may prevent accessed memory blocks from overheating. Some cross-point non-volatile memories may delay acknowledgment/completion notifications to a memory controller to allow more time for accessed memory blocks to cool.

In some implementations, resting time determination module 104 may read resting times from a serial presence detect (SPD) electrically erasable programmable read-only memory (EEPROM) and/or a register on a memory module that includes the accessed memory blocks. In some implementations, resting times may be programmed into a register (or multiple registers) in system 100. In some implementations, operating conditions of memory blocks may be, monitored, and resting time determination module 104 may adjust resting times based on operating conditions. For example, a longer resting time may be determined for a memory block with a high average operating temperature than for a memory block with a lower average operating temperature. In some implementations, wear leveling or other techniques that remap access commands to different physical addresses may be used; in such implementations, resting time determination module 104 may determine a resting time based on the final physical address.

Access regulation module 106 may prevent an access command from being issued to one of the accessed memory blocks if an amount of time, equal to the respective resting time for the one of the accessed memory blocks, has not yet elapsed after a previous access of the one of the accessed memory blocks. For example, access regulation module 106 may start a timer after an access command has been executed on a memory block and compare the timer value to the, respective resting time to determine whether another access command should be allowed to issue to the memory block. In some implementations, access regulation module 106 may block additional access commands before an amount of time equal to the respective resting time has elapsed.

In some implementations, access regulation module 106 may reschedule or delay additional access commands until a time after an amount of time equal to the respective resting time has elapsed For example, if an amount of time equal to the resting time for a first memory block has not yet elapsed after a previous access of the first memory block in response to a first access command, access regulation module 106 may delay a second access command directed at the first memory block until after an amount of time equal to the resting time has elapsed. In the meantime, access regulation module 106 may allow a third access command to be issued to another memory block (either in the same bank or a different bank) that has not been previously accessed or whose respective resting time has elapsed, the third access command may be issued before the second access command even if system 100 received the second access command before the third access command. The second access command, along with other delayed access commands, may be reassessed after a certain time interval or when no other access commands are pending.

FIG. 2 is a block diagram of an example system 200 for tracking recently accessed memory blocks using a table of indicators. System 200 may be implemented, for example, in a memory controller. In FIG. 2, system 200 includes tracking module 202, resting time determination module 204, access regulation module 206, and layout determination module 208, Modules 202, 204, and 206 of FIG. 2 may perform some of the same actions as modules 102, 104, and 106, respectively, of FIG. 1. A module may include a set of instructions encoded on a machine-readable storage medium and executable by a processor. In addition or as an alternative, a module may include a hardware device comprising electronic circuitry for implementing the functionality described below.

Tracking module 202 may store, in table 210, indicators of a predetermined number of most recently accessed memory blocks of accessed memory blocks in a cross-point non-volatile memory. For, example, tracking module 202 may store indicators of the ten most recently accessed memory blocks. Indicators stored in table 210 may include ail or a subset of the address bits corresponding to respective locations in the accessed memory blocks from which data was obtained or into which data was moved, or offset bits that can be translated to such locations. In implementations where the cross-point non-volatile memory is a memristor memory having a plurality of banks, tracking module 202 may maintain a different table of indicators for each bank, or may store all indicators for all banks in the same table.

Tracking module 202 may remove, from table 210, one of the indicators, corresponding to a first memory block of the most recently accessed memory blocks, when the respective resting time of the first memory block has elapsed after a previous access of the first memory block. In implementations where a timer is used to keep track of how much time has elapsed after an access command has been executed on the first memory block, as discussed above with respect to FIG. 1, tracking module 202 may remove the one of the indicators from table 210 when the timer value is equal to a particular value. For example, if the timer is counting up, tracking module 202 may remove the one of the indicators from table 210 when the timer value is equal to the respective resting time. If a countdown timer is used (with the start time being equal to the respective resting time), tracking module 202 may remove the one of the indicators from table 210 when the timer value is equal to zero. In response to the removal of the one of the indicators from table 210, tracking module 202 may identify a delayed access command that was delayed in response to the one of the indicators being in table 210. Access regulation module 206 may issue the identified delayed access command to the first memory block.

In some implementations, the cross-point non-volatile memory may include a memory bank that includes the first memory block, and a second memory block that does not correspond to any of the indicators in table 210. Access regulation module 206 may prevent, while the one of the indicators is in the table, an access command directed at the first memory block from being issued to the first memory block. Access regulation module 206 may issue to the second memory block, while the one of the indicators is in the table, an access command directed at the second memory block.

In some implementations, access regulation module 206 may identify at which memory block in the cross-point non-volatile memory an access command is directed. For example, access regulation module 206 may identify address bits in the access command and determine in which memory block the corresponding memory locations are. Access regulation module 206 may determine whether the identified memory block is within a predetermined physical distance of any of the memory blocks corresponding to indicators stored in table 210. For example, the predetermined physical distance may be a distance between adjacent memory blocks. Access regulation module 206 may use an address decoder to determine addresses of locations in memory blocks adjacent to the identified memory block, and may determine whether any such addresses correspond to indicators stored in table 210. In some implementations, access regulation module 206 may read the predetermined physical distance from an SPD EEPROM and/or register on a memory module that includes the cross-point non-volatile memory.

If it is determined that the identified memory block is within the predetermined physical distance of any of the memory blocks corresponding to indicators stored in table 210, access regulation module 206 may prevent the access command from being issued to the identified memory block. In some implementations, access regulation module 206 may block the access command. In some implementations, access regulation module 206 may reschedule or delay the access command until a time after an amount of time equal to an appropriate resting time has elapsed.

In some implementations, resting time determination module 204 may read a resting factor, for one of the accessed memory blocks, from a memory module that includes the cross-point non-volatile memory. As used herein, the term “resting factor” should be understood to refer to a value based on which a resting time for a memory block can be calculated. Respective resting factors may be different for different memory blocks; for example, a resting factor for a given memory block may be proportional to the operating temperature (or average operating temperature) of the given memory block. Resting time determination module 284 may also determine an access time, for the one of the accessed memory blocks. As used herein, the term “access time” should be understood to refer to the amount of time a memory block takes to process an access command. A memory block may have different access times for different types of access commands; for example, a memory block may take longer to process a write command than a read command. Resting time determination module 204 may derive a resting time based on the resting factor and access time. For example, resting time determination module 204 may multiply the resting factor by the access time to determine the resting time for the one of the accessed memory blocks.

In some implementations, resting time determination module 204 may identify, for each of the accessed memory blocks, a most recent access type. An access type may correspond to actions performed by/on a memory block in response to an access command. Access types may include, for example, “read”, “write”, “read one address”, “write one address”, “read range”, and “write range”. Resting time determination module 204 may identify a most recent access type by, for example, analyzing the last access command that was executed on the respective memory block, or by monitoring activity on the respective memory block. Respective resting times for each of the accessed memory blocks may be determined based on the respective most recent access types. For example, resting times may be longer following write access types than read access types, since write commands may take more time or more energy to process than read commands, and thus more current may be driven into a memory block during a write operation than during a read operation, resulting in more heat generated during the write operation than during the read operation.

Layout determination module 208 may determine a physical layout of a memory module that includes the cross-point non-volatile memory. In some implementations, layout determination module 208 may read physical layout information from an SPD EEPROM on the memory module. In some implementations, the physical layout of the memory module may be one of a set of standard physical layouts, and bits stored in a register of the memory module may indicate which standard physical layout is on the memory module. In such implementations, layout determination module 308 may read the bits in the appropriate register and determine to which standard physical layout the bits correspond. Resting time determination module 204 may determine the respective resting times of memory blocks based on the physical layout of the memory module. For example, memory blocks that are closer to cooling elements (e.g., heat sinks) on the memory module may have shorter resting times than memory blocks that are farther away from cooling elements.

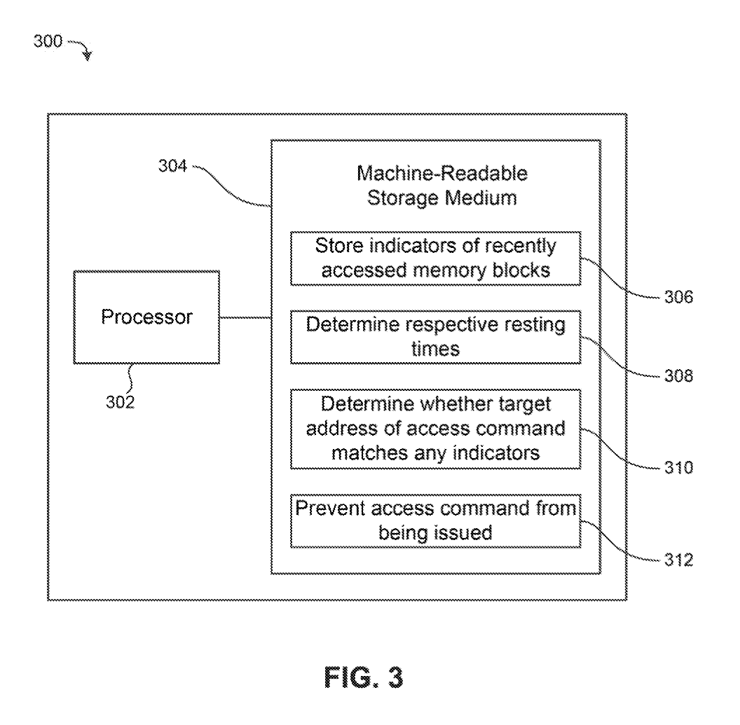

FIG. 3 is a block diagram of an example device 300 that includes a machine-readable storage medium encoded with instructions to enable enforcement of resting times for accessed memory blocks. In some examples, device 300 may implement a memory controller. In FIG. 3, system 300 includes processor 302 and machine-readable storage medium 304.

Processor 302 may include a central processing unit (CPU), microprocessor (e.g., semiconductor-based microprocessor), and/or other hardware device suitable for retrieval and/or execution of instructions stored in machine-readable storage medium 304. Processor 302 may fetch, decode, and/or execute instructions 306, 308, 310, and 312 to enable enforcement of resting times for accessed memory blocks, as described below. As an alternative or in addition to retrieving and/or executing instructions, processor 302 may include an electronic circuit comprising a number of electronic components for performing the functionality of instructions 306, 308, 310, and/or 312.

Machine-readable storage medium 304 may be any suitable electronic, magnetic, optical, or other physical storage device that contains or stores executable instructions. Thus, machine-readable storage medium 304 may include, for example, a random-access memory (RAM), an Electrically Erasable Programmable Read-Only Memory (EEPROM), a storage device, an optical disc and the like. In some implementations, machine-readable storage medium 304 may include a non-transitory storage medium, where the term “non-transitory” does not encompass transitory propagating signals. As described in detail below, machine-readable storage medium 304 may be encoded with a set of executable instructions 306, 308, 310, and 312.

Instructions 306 may store, in a table, indicators of recently accessed memory blocks in a cross-point non-volatile memory. Indicators stored in the table, may include, for example, all or a subset of the address bits corresponding to respective locations in the recently accessed memory blocks, or offset bits that can be translated to such locations. In implementations where the cross-point non-volatile memory is a memristor memory having a plurality of banks, instructions 306 may maintain a different table of indicators for each bank, or may store all indicators for all banks in the same table. In some implementations, instructions 306 may store indicators of a predetermined number of the most recently accessed memory blocks in the cross-point non-volatile memory. For example, instructions 306 may store indicators of the fifteen most recently accessed memory blocks.

Instructions 308 may determine a respective resting time for each of the recently accessed memory blocks. In some implementations, instructions 308 may read resting times from an SPD EEPROM and/or a register on a memory module that includes the recently accessed memory blocks. In some implementations, resting times may be programmed into a register (or multiple registers) in device 300. In some implementations, instructions 308 may identify, for each of the recently accessed memory blocks, a most recent access type, and may determine the respective resting times based on the respective most recent access types, as discussed above with respect to FIG. 2. In some implementations, operating conditions of memory blocks may be monitored, and instructions 308 may adjust resting times based on operating conditions. For example, a longer resting time may be determined for a memory block with a high average operating temperature than for a memory block with a lower average operating temperature. Memory blocks that are closer to cooling elements (e.g., fans, heat sinks) may have lower average operating temperatures, and thus shorter resting times, than memory blocks that are farther away from cooling elements.

In some implementations, instructions 308 may read a resting factor, for one of the recently accessed memory blocks, from a memory module that includes the recently accessed memory blocks. Instructions 308 may also determine an access time for the one of the accessed memory blocks, as discussed above with respect to FIG. 2. Instructions 308 may derive, based on the resting factor and access time, a resting time for the one of the recently accessed memory blocks. For example, instructions 308 may multiply the resting factor by the access time to determine the resting time.

Instructions 310 may determine whether a target address of an access command matches any of the indicators in the table. The term “target address”, as used herein with respect to an access, command, should be understood to refer to an address from which data is to be obtained, or into which data is to be moved, in response to the access command. In some implementations, instructions 310 may identify address or offset bits in an access command, and compare such bits to indicators in the table.

Instructions 312 may prevent an access command from being issued. For example, if the target address of an access command matches any of the indicators in the table, instructions 312 may prevent the access command from being issued to a memory block that includes the target address. In some implementations, instructions 312 may block, reschedule, or delay the access command, as discussed above with respect to FIGS. 1 and 2.

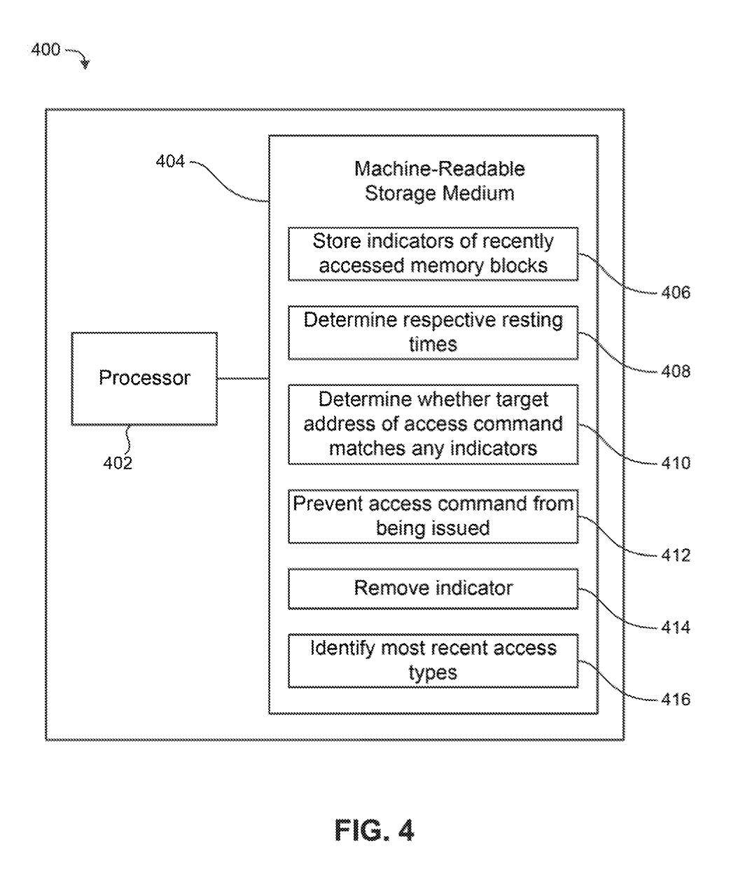

FIG. 4 is a block diagram of an example device 400 that includes a machine-readable storage medium encoded with instructions to identify access types for recently accessed memory blocks. In some examples, device 400 may implement a memory controller. In FIG. 4, system 400 includes processor 402 and machine-readable storage medium 404.

As with processor 302 of FIG. 3, processor 402 may include a CPU, microprocessor (e.g., semiconductor-based microprocessor), and/or other hardware device suitable for retrieval and/or execution of instructions stored in machine-readable storage medium 404. Processor 402 may fetch, decode, and/or execute instructions 406, 408, 410, 412, 414, and 416. As an alternative or in addition to retrieving and/or executing instructions, processor 402 may include an electronic circuit comprising a number of electronic components for performing the functionality of instructions 406, 408, 410, 412, 414, and/or 416,

As with machine-readable storage medium 304 of FIG. 3, machine-readable storage medium 404 may be any suitable physical storage device that stores executable instructions. Instructions 406, 408, 410, and 412 on machine-readable storage medium 404 may be analogous to (e.g., have functions and/or components similar to) instructions 306, 308, 310, and 312, respectively, on machine-readable storage medium 304. Instructions 406 may store, in a table, indicators of recently accessed memory blocks in a cross-point non-volatile memory. Instructions 408 may determine a respective resting time for each of the recently accessed memory blocks. Instructions 414 may remove, from the table, one of the indicators, corresponding to a memory block of the recently accessed memory blocks, when the respective resting time of the memory block, has elapsed after a previous access of the memory block. In some implementations, a timer may be used to keep track of how much time has elapsed after an access command has been executed on the memory block, and instructions 414 may remove the one of the indicators from the table when the timer value is equal to a particular value (e.g., the respective resting time, or zero), as discussed above with respect to FIG. 2. In some implementations, in response to the removal of the one of the indicators from the table, a delayed access command that was delayed in response to the one of the indicators being in the table may be identified and sent to the corresponding memory block.

Instructions 416 may identify, for each of the recently accessed memory blocks, a most recent access type. Instructions 416 may identify a most recent access type by, for example, analyzing the last access command that was executed on the respective memory block, or by monitoring activity on the respective memory block. Instructions 408 may determine the respective resting times based on the respective most recent access types, as discussed above with respect to FIG. 2.

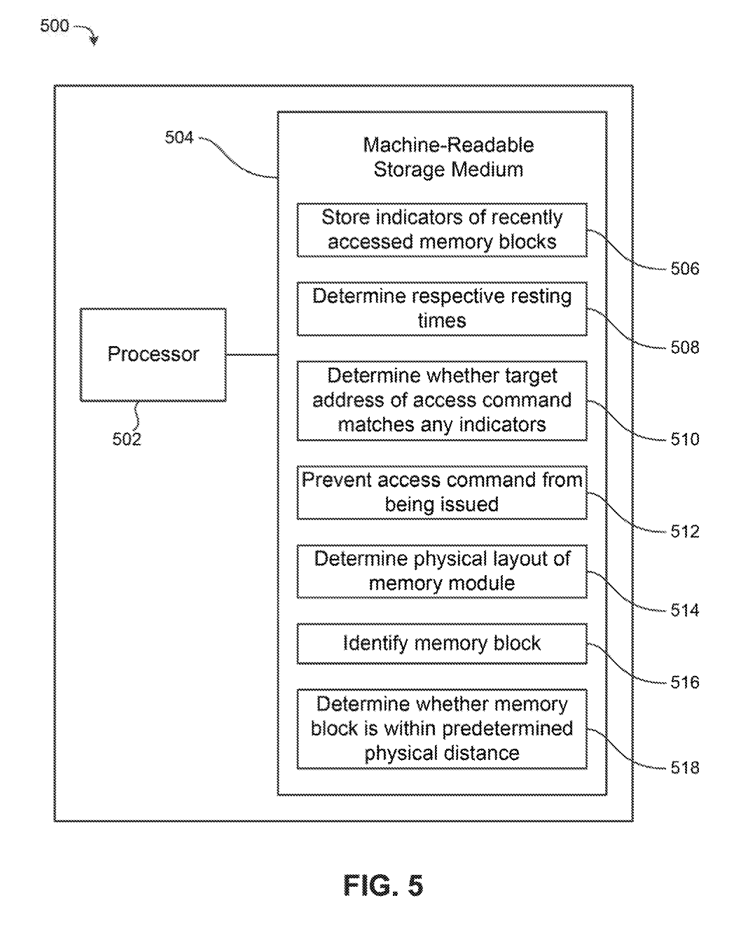

FIG. 5 is a block diagram of an example device 500 that includes a machine-readable storage medium encoded with instructions to determine a physical layout of a memory module. In some examples, device 500 may implement a memory controller. In FIG. 5, system 500 includes processor 502 and machine-readable storage medium 504.

As with processor 302 of FIG. 3, processor 502 may include a CPU, microprocessor (e.g., semiconductor-based microprocessor), and/or other hardware device suitable for retrieval and/or execution of instructions stored in machine-readable storage medium 504. Processor 502 may fetch, decode, and/or execute instructions 506, 508, 510, 512, 514, 516, and 518. As an alternative, or in addition to retrieving and/or executing instructions, processor 502 may include an electronic circuit comprising a number of electronic components for performing the functionality of instructions 506, 508, 510, 512, 514, 516, and/or 518,

As with machine-readable storage medium 304 of FIG. 3, machine-readable storage medium 504 may be any suitable physical storage device that stores executable instructions. Instructions 506, 508, 510, and 512 on machine-readable storage medium 504 may be analogous to instructions 306, 308, 310, and 312, respectively, on machine-readable storage medium 304. Instructions 506 may store, in a table, indicators of recently accessed memory blocks in a cross-point non-volatile memory. Instructions 514 may determine a physical layout of a memory module that includes the cross-point non-volatile memory. In some implementations, instructions 514 may read physical layout information from an SPD EEPROM on the memory module. In some implementations, instructions 514 may read, from a register of the memory module, bits that indicate which of a set of standard physical layouts is on the memory module, as discussed above with respect to FIG. 2. Instructions 508 may determine, based on the physical layout, a respective resting time for each of the recently accessed memory blocks. For example, memory blocks that are closer to cooling elements (e.g., heat sinks) on the memory module may have shorter resting times than memory blocks that are farther away from cooling elements.

Instructions 516 may identify at which memo y block in the cross-point non-volatile memory an access command is directed. For example, instructions 516 may identify address bits in the access command and determine in which memory block the corresponding memory location(s) is/are. In some implementations, instructions 516 may identify offset bits in the, access command, translate the offset bits to memory location(s), and determine in which memory block the memory location(s) is/are.

Instructions 518 may determine whether the identified memory block is within a predetermined physical distance of any of the memory blocks corresponding to indicators stored in a table. For example, the predetermined physical distance may be a distance between adjacent memory blocks. Instructions 518 may use an address decoder to determine addresses of locations in memory blocks adjacent to the identified memory block, and may determine whether any such addresses correspond to indicators stored in the table. In some implementations, instructions 518 may read the predetermined physical distance from an SPD EEPROM, and/or register on a memory module that includes the identified memory block. Instructions 512 may prevent the access command from being issued to the identified memory block if it is determined that the identified memory block is within the predetermined physical distance of any of the memory blocks corresponding to indicators stored in the table. For example, instructions 512 may block, reschedule, or delay the access command until a time after an amount of time equal to an appropriate resting time has elapsed.

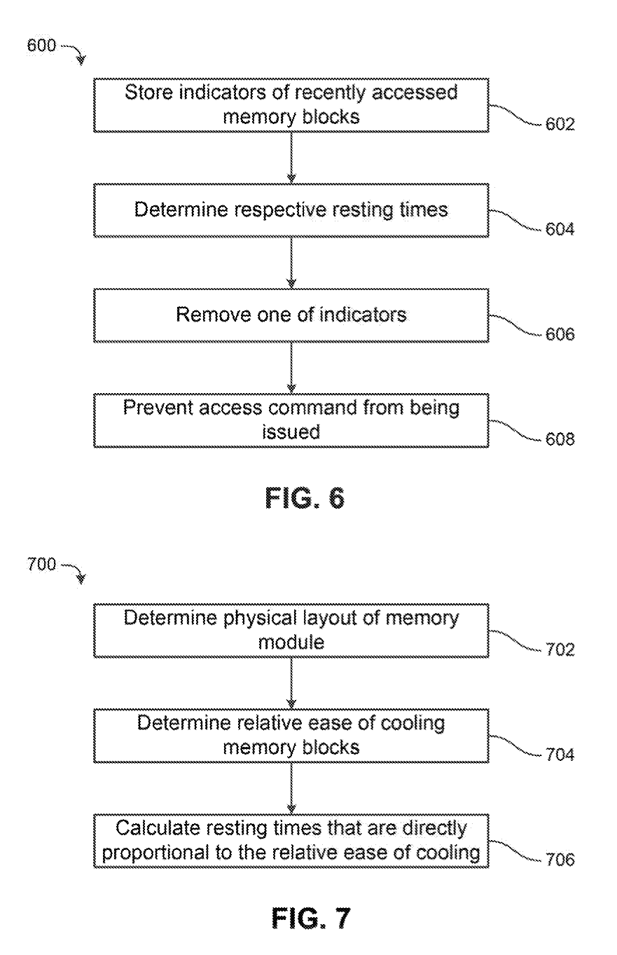

Methods related to enforcing resting times for'accessed memory blocks are discussed with respect to FIGS. 6-8. FIG. 6 is a flowchart of an example method 600 for tracking recently accessed memory blocks. Although execution of method 600 is described below with reference to processor 402 of FIG. 4, it should be understood that execution of method 600 may be performed by other suitable devices, such as processors 302 and 502 of FIGS. 3 and 5, respectively. Method 600 may be implemented in the form of executable instructions stored on a machine-readable storage medium and/or in the form of electronic circuitry

Method 600 may start in block 602, where processor 402 may store, in a table, indicators of recently accessed memory blocks in a cross-point non-volatile memory. Indicators stored in the table may include, for example, all or a subset of the address bits corresponding to respective locations in the recently accessed memory blocks, or offset bits that can be translated to such locations. In implementations where the cross-point non-volatile memory is a memristor memory having a plurality of banks, processor 402 may maintain a different table of indicators for each bank, or may store all indicators for all banks in the same table. In some implementations, processor 402 may store indicators of a predetermined number (e.g., eight) of the most recently accessed memory blocks in the cross-point non-volatile memory.

In block 604, processor 402 may determine a respective resting time for each of the recently accessed memory blocks. In some implementations, processor 402 may read resting times from an SPD EEPROM and/or a register on a memory module that includes the recently accessed memory blocks. In some implementations, resting times may be programmed into a register (or multiple registers) of a memory controller (e.g. device 400) that controls access to the memory module. In some implementations, processor 402 may identify, for each of the recently accessed memory blocks, a most recent access type, and may determine the respective resting times based on the respective most recent access types. In some implementations, processor 402 may derive a resting time based on a resting factor and an access time (e.g., by multiplying a resting factor by an access time), as discussed above with respect to FIG. 2.

In block 606, processor 402 may remove, from the table, one of the indicators, corresponding to a first memory block of the recently accessed memory blocks, when the respective resting time of the first memory block has elapsed after a previous access of the first memory block. In some implementations, a timer may be used to keep track of how much time has elapsed after the most recent access command directed at the first memory block has been executed on the first memory block. Processor 402 may remove the one of the indicators from the table when the timer value is equal to a particular value (e.g., the respective resting time, or zero), as discussed above with respect to FIG. 2.

In block 608, processor 402 may prevent, if a target address of an access command matches any of the indicators in the table, the access command from being issued to a memory block that includes the target address. For example, processor 402 may identify address or offset bits in the access command, and compare such bits to indicators in the table. In some implementations, processor 402 may block, reschedule, or delay the access command, as discussed above with respect to FIGS. 1 and 2.

FIG. 7 is a flowchart of an example method 700 for determining resting times for memory blocks. Although execution of method 700 is described below with reference to processor 502 of FIG. 5, it should be understood that execution of method 700 may be performed by other suitable devices, such as processors 302 and 402 of FIGS. 3 and 4, respectively. Some blocks of method 700 may be performed in parallel with and/or after method 600. Method 700 may be implemented in the form of executable instructions stored on a machine-readable storage medium and/or in the form of electronic circuitry.

Method 700 may start in block 702, where processor 502 may determine a physical layout of a memory module that includes a cross-point non-volatile memory. In some implementations, processor 502 may read physical layout information from an SPO EEPROM on the memory module. In some implementations, processor 502 may read, from a register of the memory module, bits that indicate which of a set of standard physical layouts is on the memory module, as discussed above with respect to FIG. 2.

In block 704, processor 502 may determine relative ease of cooling recently accessed memory blocks on the memory module. For example, processor 502 may identify locations of cooling elements such as fans and/or heat sinks relative to the recently accessed memory blocks on the memory module. Cooling elements on the memory module or in the, same chassis as the memory module may lower average operating temperatures of memory blocks on the memory module by dissipating heat that is generated when current is driven into the memory blocks (e.g., during read and write operations). Memory blocks that are closer to cooling elements may be easier to cool (and thus have lower operating temperatures) than memory blocks that are farther away from cooling elements. For example, memory blocks that are farther away from packaged heat sinks designed to dissipate internally generated heat from memory accesses may be more difficult to cool than memory blocks that are closer to packaged heat sinks.

In block 706, processor 502 may determine respective resting times for the recently accessed memory blocks by calculating resting times that are directly proportional to the relative ease of cooling the respective recently accessed memory blocks. For example, memory blocks that are closer to cooling elements may have shorter resting times than memory blocks that are farther away from cooling elements. Memory blocks that are closer to cooling elements may be cooled more quickly and easily by the cooling elements than memory blocks that are farther away from the cooling elements, and thus may be able to tolerate shorter resting times without performance degradation,

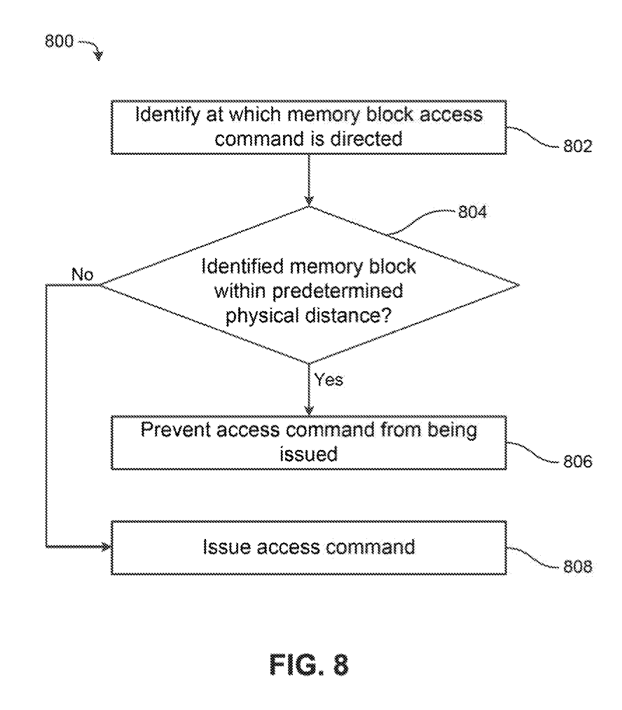

FIG. 8 is a flowchart of an example method 800 for preventing an access command from being issued to a memory block within a predetermined physical distance of a recently accessed memory block. Although execution of method 800 is described below with reference to processor 502 of FIG. 5, it should be understood that execution of method 800 may be performed by other suitable devices, such as processors 302 and 402 of FIGS. 3 and 4, respectively. Some, blocks of method 800 may be performed in parallel with and/or after method 600 or 700. Method 800 may be implemented in the form of executable instructions stored on a machine-readable storage medium and/or in the form of electronic circuitry.

Method 800 may start in block 802, where processor 502 may identify at which memory block in a cross-point non-volatile memory an access command is directed. For example, processor 502 may identify address bits in the access command and determine in which memory block the corresponding memory location(s) is/are, in some implementations, processor 502 may identify offset bits in the access command, translate the offset bits to memory cation(s), and determine in which memory block the memory location(s) is/are.

In block 804, processor 502 may determine whether the identified memory block is within a predetermined physical distance of any of the memory blocks corresponding to indicators stored in a table. The indicators in the table may correspond to respective recently accessed memory blocks in the cross-point non-volatile memory. In some implementations, the predetermined physical distance may be a distance between adjacent memory blocks. Processor 502 may use an address decoder to determine addresses of locations in memory blocks adjacent to the identified memory block, and may determine whether any such addresses correspond to indicators stored in the table. In some implementations, processor 502 may read the predetermined physical distance from an SPD EEPROM and/or register on a memory module that includes the identified memory block.

If, in block 804, processor 502 determines that the identified memory block is within the predetermined physical distance of any of the memory blocks corresponding to indicators stored in the table, method 800 may proceed to block 806, in which processor 502 may prevent the access command from being issued. In some implementations, processor 502 may block, reschedule, or delay the access command, as discussed above with respect to FIGS. 1 and 2. If, in block 804, processor 502 determines that the identified memory block is not within the predetermined physical distance of any of the memory blocks corresponding to indicators stored in the table, method 800 may proceed to block 808, in which processor 502 may issue the access command to the appropriate memory block in the cross-point non-volatile memory.

The foregoing disclosure describes enforcing resting times for accessed memory blocks. Example implementations described herein enable tracking of array access separately from bank access, and minimization of local heating. Thus, memory reliability and longevity may be extended, and the effects of malicious access patterns may be reduced.

We claim:

1. A system comprising:
a tracking module to track accessed memory blocks in a cross point non-volatile memory;
a resting time determination module to determine a respective resting time or each of the accessed memory blocks; and
an access regulation module to prevent a first access command from being issued to one of the accessed memory blocks if an amount of time, equal to the respective resting time for the one of the accessed memory blocks, has not yet elapsed after a previous access of the one of the accessed memory blocks.

2. The system of claim 1, wherein the cross-point non-volatile memory is a memristor memory, and wherein the accessed memory blocks are arrays of the memristor memory.

3. The system of claim 1, further comprising a layout determination module to determine a physical layout of a memory, module that includes the cross-point non-volatile memory, wherein the resting time determination module is to determine the respective resting times based on the physical layout.

4. The system of claim 1, wherein the resting time determination module is further to:
read a resting factor, for the one of the accessed memory blocks, from a memory module that includes the cross-point non-volatile memory;
determine an access time for the one of the accessed memory blocks; and
derive, based on the resting factor and access time, the resting time for the one of the accessed memory blocks.

5. The system of claim 1, wherein the resting time determination module is further to identify, for each of the accessed memory blocks, a most recent access type, wherein the respective resting times are determined based on the respective most recent access types.

6. The system of claim 1, wherein the tracking module is further to:
store, in a table, indicators of a predetermined number of most recently accessed memory blocks of the accessed memory blocks:
remove, from the table, one of the indicators, corresponding to a first memory block of the most recently accessed memory blocks, when the respective resting time of the first memory block has elapsed after a previous access of the first memory block; and
identify, in response to the removal of the one of the indicators from the table, a delayed access command that was delayed in response to the one of the indicators being in the table, wherein the access regulation module is further to issue the identified delayed access command to the first memory block.

7. The system of claim 6, wherein the access regulation module is further to:
identify at which memory block in the cross-point non-volatile memory a second access command is directed;
determine whether the identified memory block is within a predetermined physical distance of any of the memory blocks corresponding to indicators stored in the table; and
prevent the second access command from being, issued to the identified memory block if it is determined that the identified memory block is within the predetermined physical distance of any of the memory blocks corresponding to indicators stored in the table.

8. The system of claim 6, wherein:
the cross-point non-volatile memory comprises a memory bank that includes:
the first memory block, and
a second memory block that does not correspond to any of the indicators in the table; and
the access regulation module is further to: <prevent, while the one of the indicators is in the table, an access command directed at the first memory block from being issued to the first memory block; and
issue to the second memory block, while the one of the indicators is in the table, an access command directed at the second memory block

9. A machine-readable storage medium encoded with instructions executable by a processor, the machine-readable storage medium comprising:
instructions to store, in a table, indicators of recently accessed memory blocks in a cross-point non-volatile memory;
instructions to determine a respective resting time for each of the recently accessed memory blocks;
instructions to determine whether a target address of an access command matches any of the indicators in the table; and
instructions to prevent, if the target address of the access command matches any of the indicators in the table, the access command from being issued to a memory block that includes the target address.

10. The machine-readable storage medium of claim 9, further comprising instructions to remove, from the table, one of the indicators, corresponding to a first memory block of the recently accessed memory blocks, when the respective resting time of the first memory block has elapsed after a previous access of the first memory block.

11. The machine-readable storage medium of claim 9, further comprising instructions to determine a physical layout of a memory module that includes the cross-point non-volatile memory, wherein the respective resting times are determined based on the physical layout.

12. The machine-readable storage medium of claim 9, further comprising:
instructions to identify at which memory block in the cross-point non-volatile memory the access command is directed;
instructions to determine whether the identified memory block is within a predetermined physical distance of any of the memory blocks corresponding to indicators stored in the table; and
instructions to prevent the access command from being issued to the identified memory block if it is determined that the identified memory block is within the predetermined physical distance of any of the memory blocks corresponding to indicators stored in the table.

13. A method comprising:
storing, in a table, indicators of recently accessed memory blocks in a cross-point non-volatile memory;
determining a respective resting time for each of the recently accessed memory blocks;
removing, from the table, one of the indicators, corresponding to a first memory block of the recently accessed memory blocks, when the respective resting time of the first memory block has elapsed after a previous access of the first memory block; and
preventing, if a target address of an access command matches any of the indicators in the table, the access command from being issued to a memory block that includes the target address.

14. The method of claim 13, further comprising.
determining a physical layout of memory module that includes the cross-point non-volatile memory; and
determining relative ease of cooling the recently accessed memory blocks on the memory module;
wherein determining the respective resting times comprises calculating resting times that are directly proportional to the relative ease of cooling the respective recently accessed memory blocks.

15. The method of claim 13, further comprising:
identifying at which memory block in the cross-point non-volatile memory the access command is directed;
determining whether the identified memory block is within a predetermined physical distance of any of the memory blocks corresponding to indicators stored in the table; and
preventing the access command from being issued to the identified memory block if it is, determined that the identified memory block is within the predetermined physical distance of any of the memory blocks corresponding to indicators stored in the table.
